(19) United States
(12) Patent Application Publication
(10) Pub. No.: US 2015/0042636 A1
(43) Pub. Date: Feb. 12, 2015

(54) LIQUID CRYSTAL DISPLAY DEVICE AND LIQUID CRYSTAL DISPLAY DEVICE DRIVING METHOD

(71) Applicant: Sharp Kabushiki Kaisha, Osaka-shi, Osaka (JP)

(72) Inventors: Kohji Saitoh, Osaka-shi (JP); Akihisa Iwamoto, Osaka-shi (JP); Jun Nakata, Osaka-shi (JP); Masaki Uehata, Osaka-shi (JP); Tomohiko Nishimura, Osaka-shi (JP); Masami Ozaki, Osaka-shi (JP)

(21) Appl. No.: 14/375,444

(22) PCT Filed: Jan. 28, 2013
(86) PCT No.: PCT/JP2013/051768

§ 371 Date: Jul. 30, 2014

(30) Foreign Application Priority Data
Jan. 31, 2012 (JP) 2012-019152

(51) Int. Cl. G02F 1/133; G09G 3/36; H01L 27/12; G02F 1/1368; G02F 1/1362

(52) U.S. Cl. CPC G02F 1/13306; G02F 1/1368; G02F 1/136286; G02F 1/136277; H01L 27/1225; G09G 3/3674; G09G 2310/067; G09G 2310/0243
USPC 345/212; 349/43; 345/87

(57) ABSTRACT

The present invention is intended to make it unlikely that, in a case where a transistor is turned on in preparation for an operation to turn off a power source of a liquid crystal display device, a DC voltage becomes applied across a pixel even if potential variation (kickback) occurs at a pixel electrode in reaction to a change in status of the transistor from an on state to an off state. A liquid crystal display device of the present invention includes: a data signal line; a scan signal line; a pixel electrode; a transistor connected to (i) the data signal line, (ii) the scan signal line, and (iii) the pixel electrode; and a common electrode, the liquid crystal display device being configured to turn on the transistor during a power-off sequence by causing a change in an electric potential of the scan signal line, the electric potential of the scan signal line increasing up to a first electric potential at a first timing after the change is initiated, and an output electric potential supplied to the data signal line at a second timing which comes after the first timing being set to a value higher than an output electric potential supplied to the common electrode at the second timing.

### TECHNICAL FIELD

The present invention relates to a liquid crystal display device.

### BACKGROUND ART

In a case where a DC voltage is applied across a pixel (liquid crystal capacitor including a pixel electrode, a counter electrode, and liquid crystals sandwiched between the pixel electrode and the counter electrode) due to electric charge remaining at the pixel electrode when a liquid crystal display device is turned off, image sticking and/or flickering occur. This ruins the reliability of the liquid crystal display device.

Patent Literature 1 discloses a technology in which a transistor is turned on during a power-off sequence of a liquid crystal display device so as to intentionally discharge electric charge that is remaining at a pixel electrode.

### CITATION LIST

### Patent Literature

Patent Literature 1
Japanese Patent Application Publication, Tokukai, No. 2006-011311 A

### SUMMARY OF INVENTION

### Technical Problem

The inventors of the present invention found the following problem: (i) Even if a transistor is turned on during a power-off sequence as is the case of Patent Literature 1, potential variation (kickback) is induced by surrounding parasitic capacitance when the transistor is changed from an on state to an off state (when an electric potential of the transistor changes). This causes a DC voltage to be applied across a pixel (liquid crystal capacitor). (ii) A liquid crystal display device having good off-state characteristics of a transistor, in particular, may cause a DC voltage to be applied across a pixel for an extended period of time (since self-discharge via the transistor is suppressed).

An object of the present invention is to make it unlikely for a DC voltage to be applied across a pixel even if potential variation (kickback) occurs at a pixel electrode in reaction to a change in status of a transistor from an on state to an off state in a case where the transistor is turned on during a power-off sequence of a liquid crystal display device.

### Solution to Problem

A liquid crystal display device of the present invention includes: a data signal line; a scan signal line; a pixel electrode; a transistor connected to (i) the data signal line, (ii) the scan signal line, and (iii) the pixel electrode; and a common electrode, the liquid crystal display device being configured to turn on the transistor during a power-off sequence by causing a change in an electric potential of the scan signal line, the electric potential of the scan signal line increasing up to a first electric potential at a first timing after the change is initiated, and an output electric potential supplied to the data signal line at a second timing which comes after the first timing being set to a value higher than an output electric potential supplied to the common electrode at the second timing.

### Advantageous Effects of Invention

A liquid crystal display device of the present invention makes it unlikely for a DC voltage to be applied across a pixel even if kickback occurs at a pixel electrode in reaction to a change in status of a transistor from an on state to an off state in a case where the transistor is turned on at the time of turning off the liquid crystal display device.

### BRIEF DESCRIPTION OF DRAWINGS

FIG. 1 is a timing chart showing a power-off sequence of Embodiment 1.

FIG. 2 is a block diagram illustrating a liquid crystal display device of Embodiment 1.

FIG. 3 is an equivalent circuit diagram illustrating part of the configuration illustrated in FIG. 2.

FIG. 4 is a timing chart showing the power-off sequence (including potential variation at a data signal line) of Embodiment 1.

FIG. 5 is a timing chart showing the power-off sequence (including potential variation at a pixel electrode) of Embodiment 1.

FIG. 6 is a timing chart showing the power-off sequence (including potential variation at a common electrode) of Embodiment 1.

FIG. 7 is a timing chart showing another form of Embodiment 1.

FIG. 8 is a timing chart showing a power-off sequence of Embodiment 2.

FIG. 9 is a timing chart showing the power-off sequence (including potential variation at a data signal line) of Embodiment 2.

FIG. 10 is a timing chart showing the power-off sequence (including potential variation at a pixel electrode) of Embodiment 2.

FIG. 11 is a timing chart showing the power-off sequence (including potential variation at a common electrode) of Embodiment 2.

FIG. 12 is a timing chart showing a power-off sequence of Embodiment 3.

FIG. 13 is a timing chart showing the power-off sequence (including potential variation at a data signal line) of Embodiment 3.

FIG. 14 is a timing chart showing the power-off sequence (including potential variation at a pixel electrode) of Embodiment 3.

FIG. 15 is a timing chart showing the power-off sequence (including potential variation at a common electrode) of Embodiment 3.

FIG. 16 is a timing chart showing a modification of FIG. 13.

FIG. 17 is a timing chart showing a modification of FIG. 14.

FIG. 18 is a timing chart showing a modification of FIG. 15.

FIG. 19 is a timing chart showing another form of Embodiment 3.

FIG. 20 is a timing chart showing an example of supplying power to a driver in each embodiment.

FIG. 21 is a timing chart showing an example of a correlation between an electric potential of a scan signal line and how power is supplied to a driver in each embodiment.

FIG. 22 is a timing chart showing another example of a correlation between an electric potential of a scan signal line and how power is supplied to a driver in each embodiment.

FIG. 23 is a graph showing a characteristic of an oxide semiconductor.

FIG. 24 is a timing chart showing a power-off sequence of a reference example.

FIG. 25 is a timing chart showing the power-off sequence (including potential variation at a data signal line) of the reference example.

FIG. 26 is a timing chart showing the power-off sequence (including potential variation at a common electrode) of the reference example.

FIG. 27 is a timing chart showing the power-off sequence (including potential variation at a pixel electrode) of the reference example.

### DESCRIPTION OF EMBODIMENTS

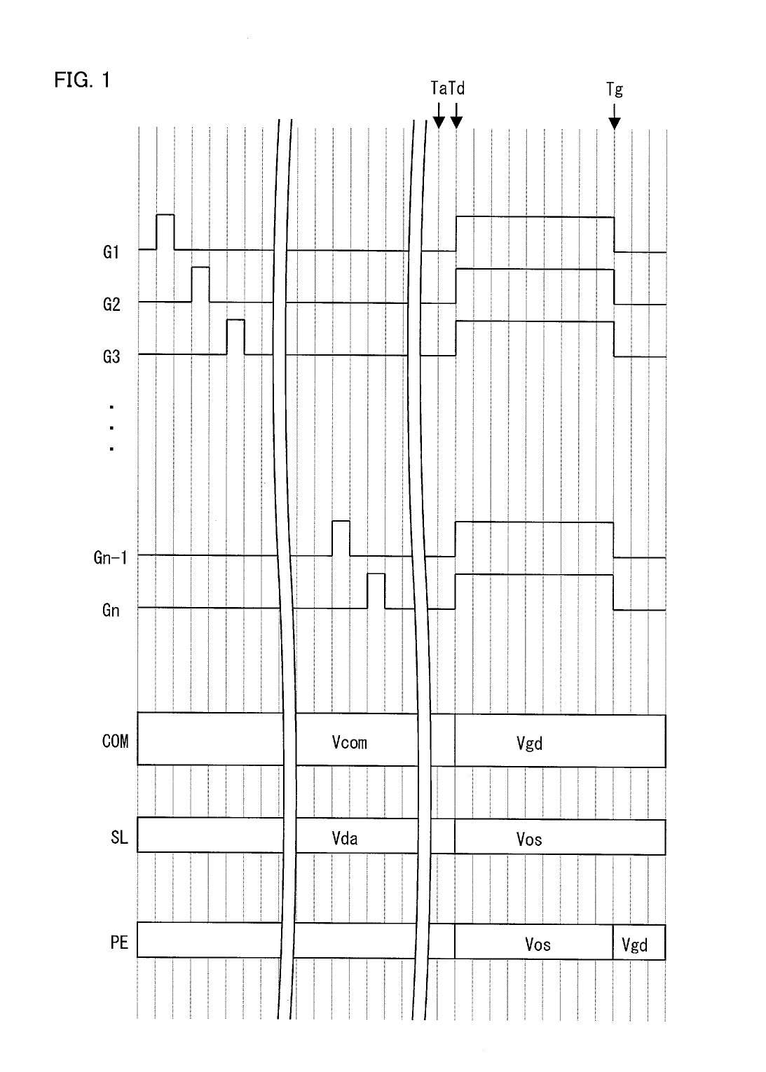

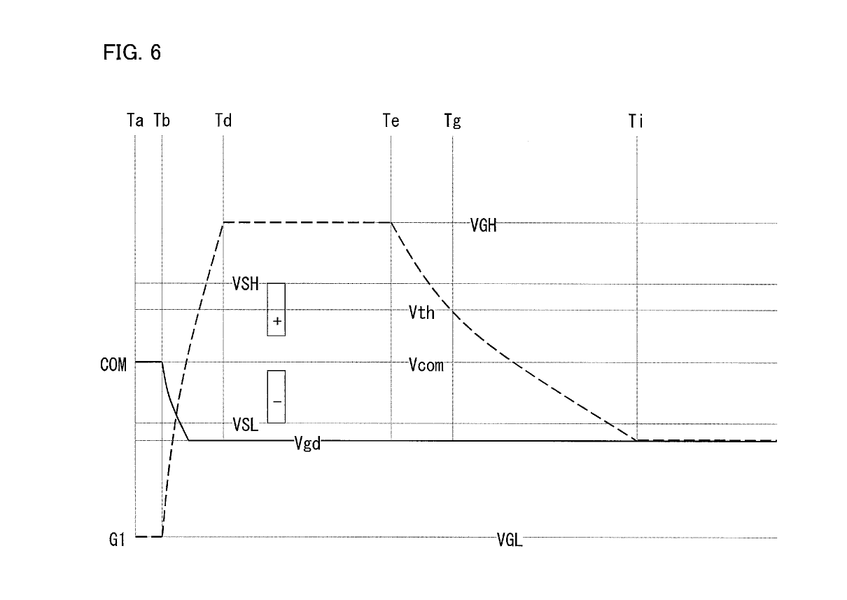

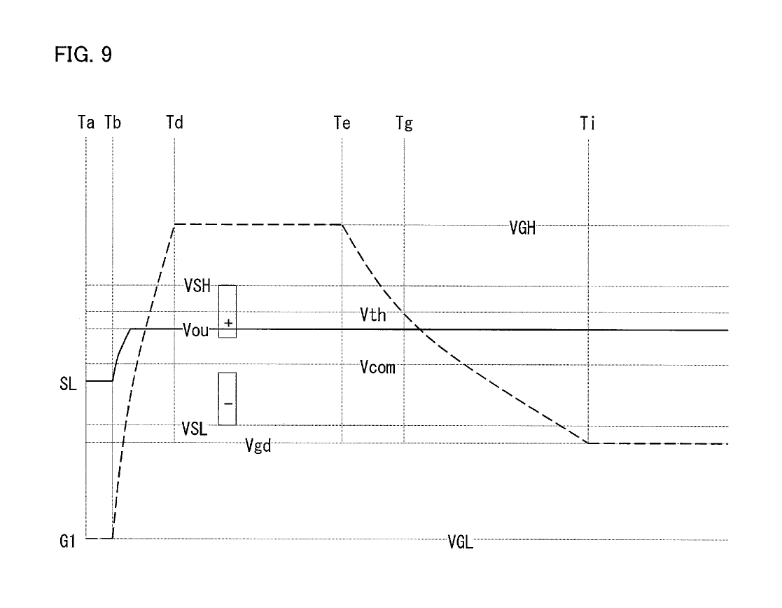

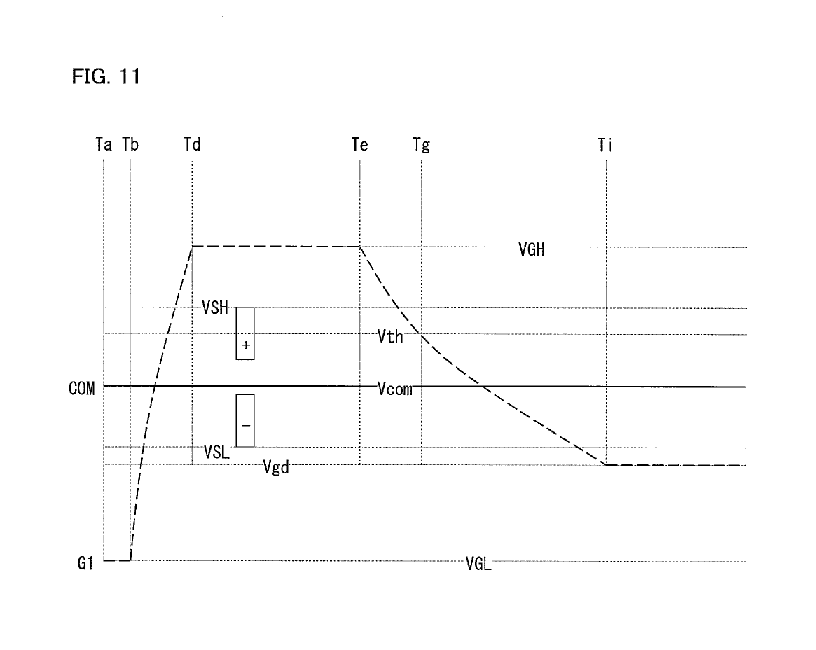

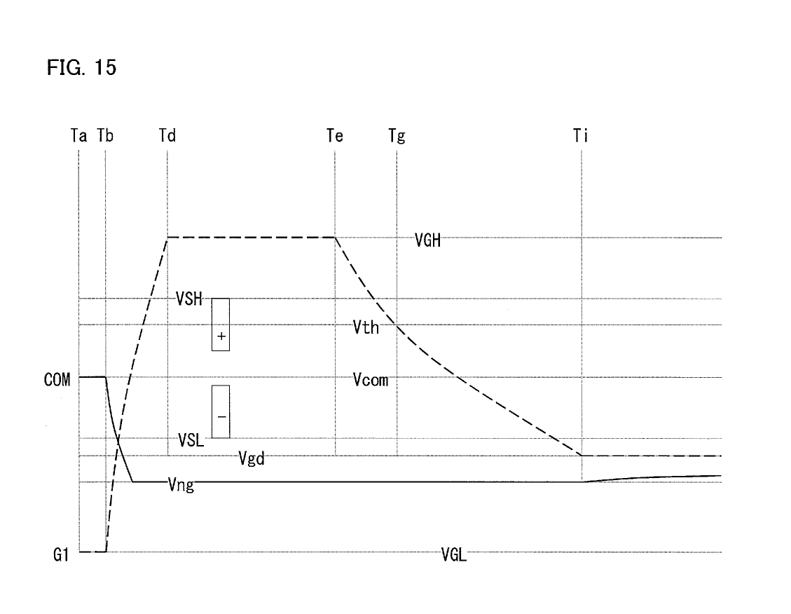

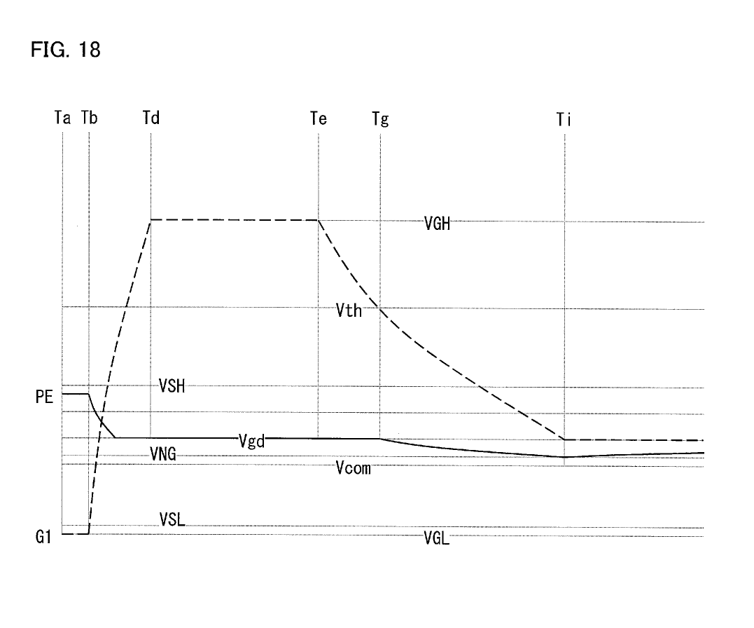

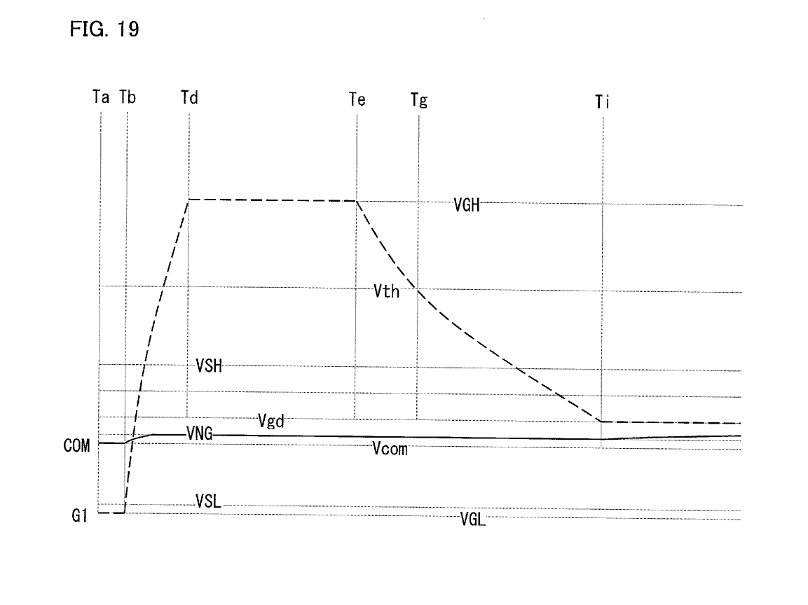

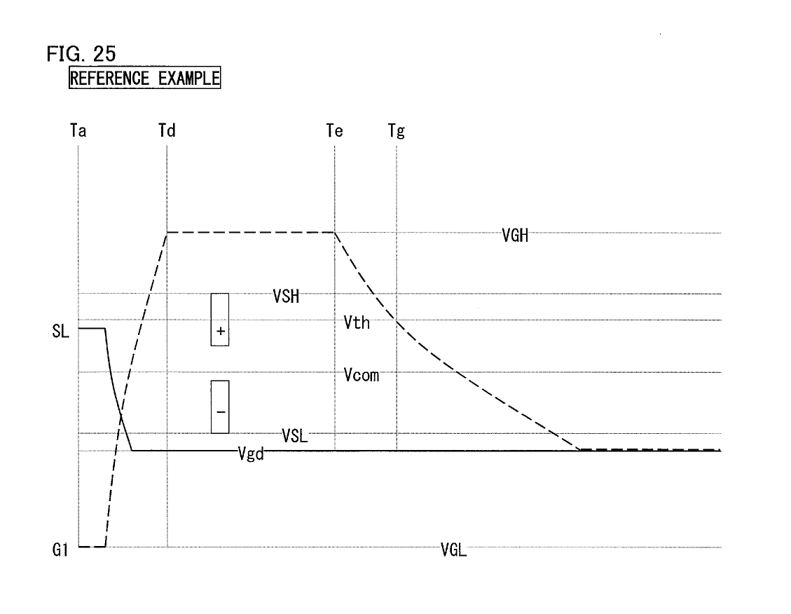

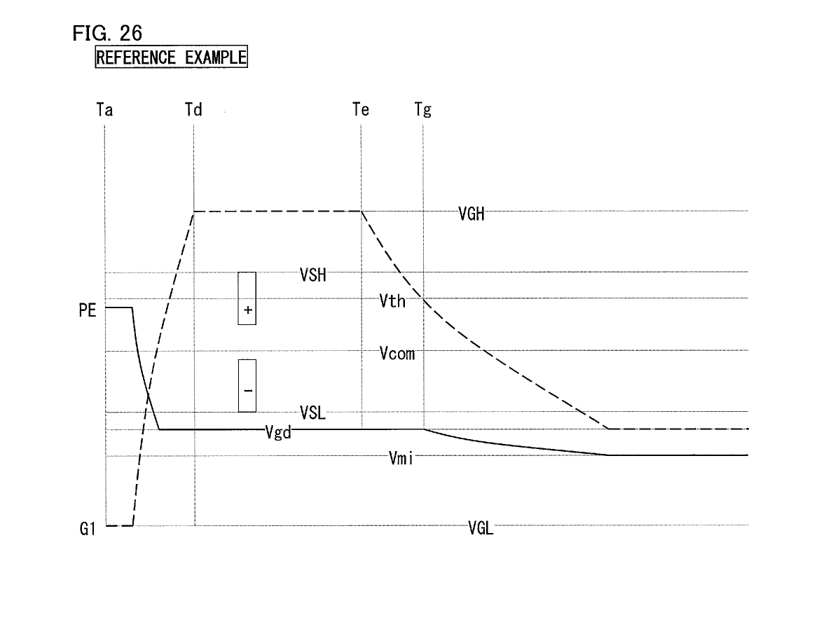

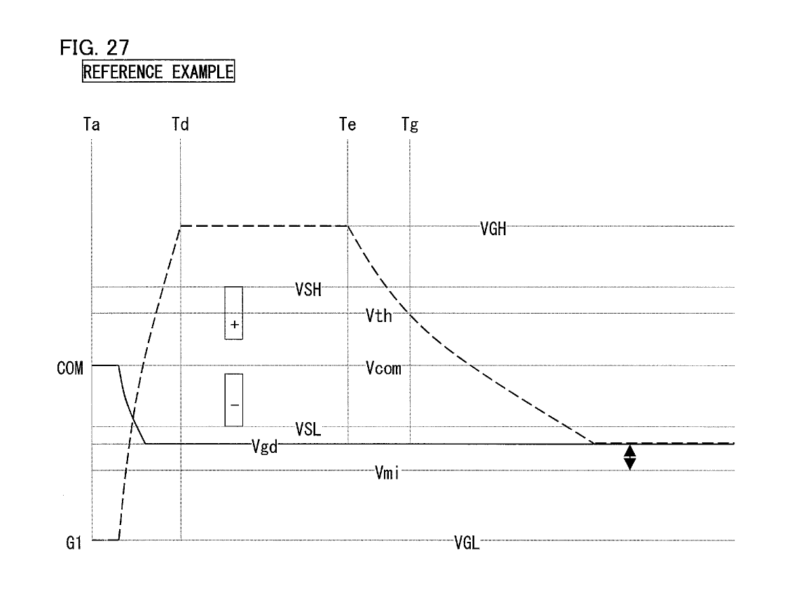

The following description will discuss embodiments of the present invention with reference to FIGS. 1 through 27.

### Embodiment 1

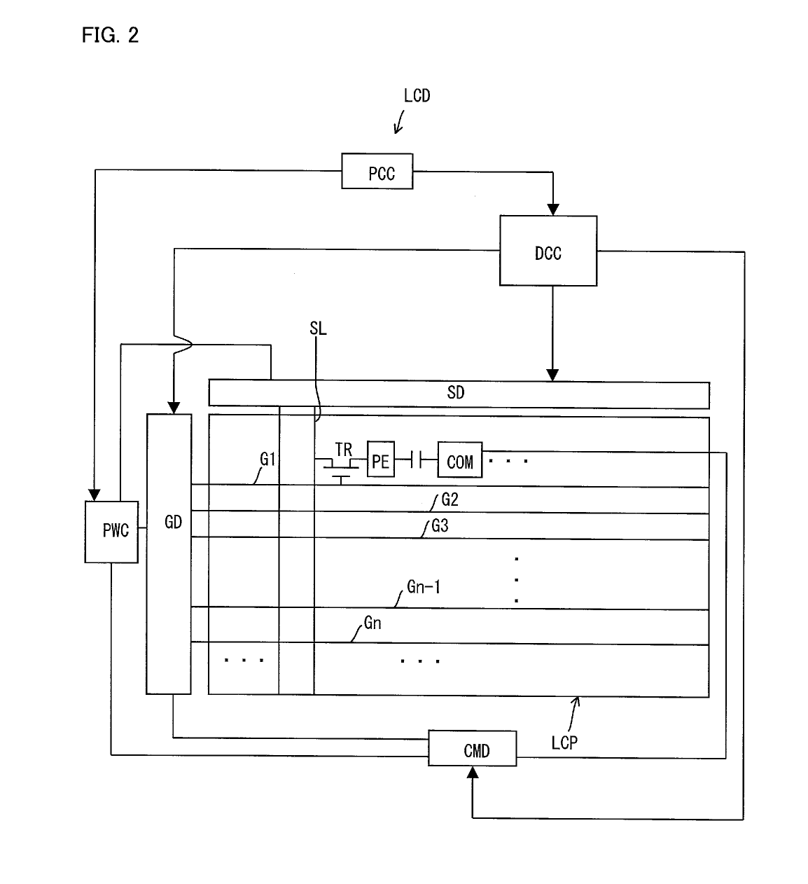

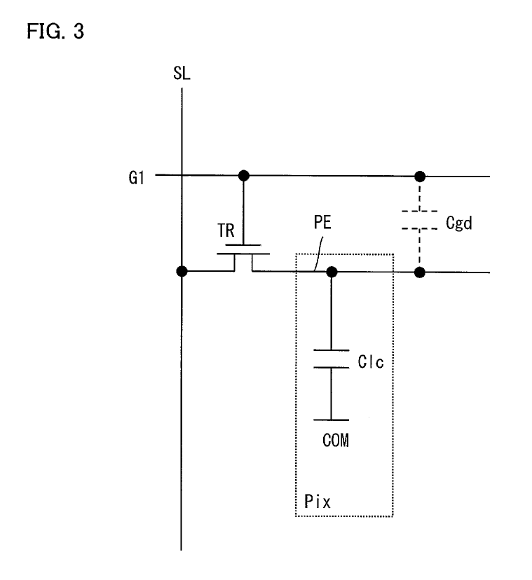

FIG. 2 is a block diagram illustrating a configuration of a liquid crystal display device of the present embodiment. FIG. 3 is an equivalent circuit diagram illustrating part of the configuration illustrated in FIG. 2. As illustrated in FIGS. 2 and 3, a liquid crystal display device LCD of Embodiment 1 includes (i) a liquid crystal panel LCP including two substrates (not illustrated) and a liquid crystal layer (not illustrated) sandwiched between the two substrates, (ii) a display control circuit DCC, (iii) a source driver SD, (iv) a gate driver GD, (v) a common electrode driver CMD, (vi) a power supply circuit PWC, and (vii) a power supply control circuit PCC.

The liquid crystal panel LCP includes scan signal lines G1 through Gn, a data signal line SL, a pixel electrode PE, a transistor (thin film transistor, TFT) TR, and a common electrode COM. The transistor TR has (i) a gate electrode which is connected to the scan signal line G1, (ii) a source electrode which is connected to a the data signal line SL, and (iii) a drain electrode which is connected to the pixel electrode PE. As illustrated in FIG. 3, a pixel capacitance (liquid crystal capacitance) Clc is formed by (a) the pixel electrode PE and the common electrode COM of a pixel Pix and (b) the liquid crystal layer. Note that a parasitic capacitance Cgd is formed between the gate electrode (scan signal line G1) of the transistor TR and the drain electrode (pixel electrode PE) of the transistor TR.

The source driver SD drives the data signal line SL (generates an output electric potential to be supplied to the data signal line SL). The gate driver GD drives the scan signal lines G1 through Gn. The common electrode driver CMD drives the common electrode COM (generates an output electric potential to be supplied to the common electrode COM). The display control circuit DCC (i) includes a timing controller and an image processing circuit and (ii) controls the source driver SD, the gate driver GD, and the common electrode driver CMD. The power supply control circuit PCC controls the power supply circuit PWC in response to instruction from a user or a system. The power supply circuit PWC is controlled by the power supply control circuit PCC to supply various power supply voltages to the source driver SD, the gate driver GD, and the common electrode driver CMD.

The liquid crystal display device of Embodiment 1 is configured such that in a case where instruction is given to turn off a power supply at time Ta, (i) electric potentials of the scan signal lines G1 through Gn rise at time Tb so as to turn on the transistor TR, (ii) an offset potential Vos is supplied to the data signal line SL at the time Tb, (iii) a ground potential Vgd is supplied to the common electrode COM at the time Tb, and (iv) the transistor TR becomes turned off at time Tg which comes after the time Tb (see FIG. 1).

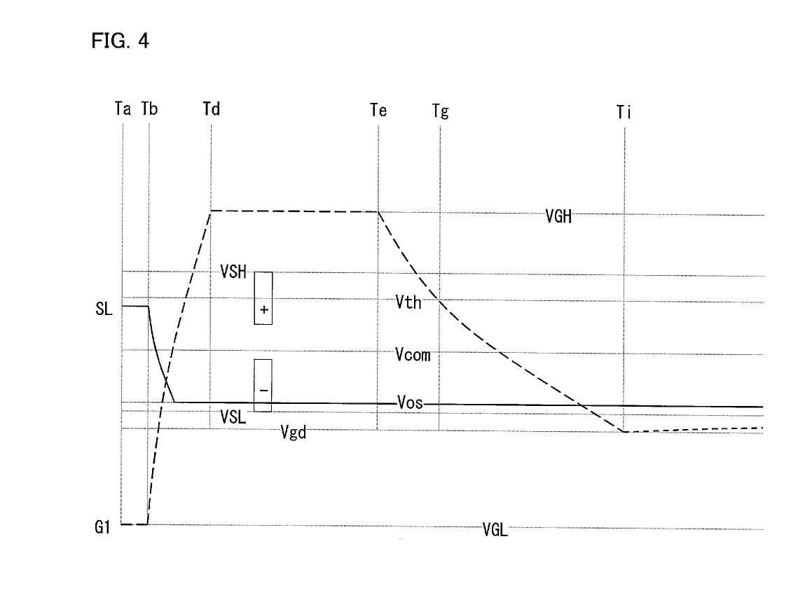

The details (sequence after the time Tb) of FIG. 1 are shown in FIGS. 4 through 6. It is assumed that (i) the liquid crystal panel LCP is of a normally-black type and the transistor TR is of an n-channel type and (ii) the following is true: gate-off potential VGL<ground potential Vgd<during-negative-driving lowest gradation potential VSL<offset potential Vos<display center potential (potential of common electrode during normal display) Vcom<transistor threshold potential Vth<during-positive-driving highest gradation potential VSH<gate-on potential VGH.

First, at the time Tb, (i) rising of the electric potential of the scan signal line G1 is initiated, (ii) the offset potential Vos is supplied to the data signal line SL, and (iii) the ground potential Vgd is supplied to the common electrode COM. At time Td (first timing), the electric potential of the scan signal line G1 reaches the gate-on potential VGH (first electric potential) which is higher than the threshold potential Vth of the transistor.

At time Te which comes after the time Td, the electric potential of a gate pulse signal (electric potential of the scan signal line G1) turns downwards. Then, the transistor TR becomes turned off around the time Tg at which the electric potential of the scan signal line G1 becomes equal to the threshold potential Vth of the transistor.

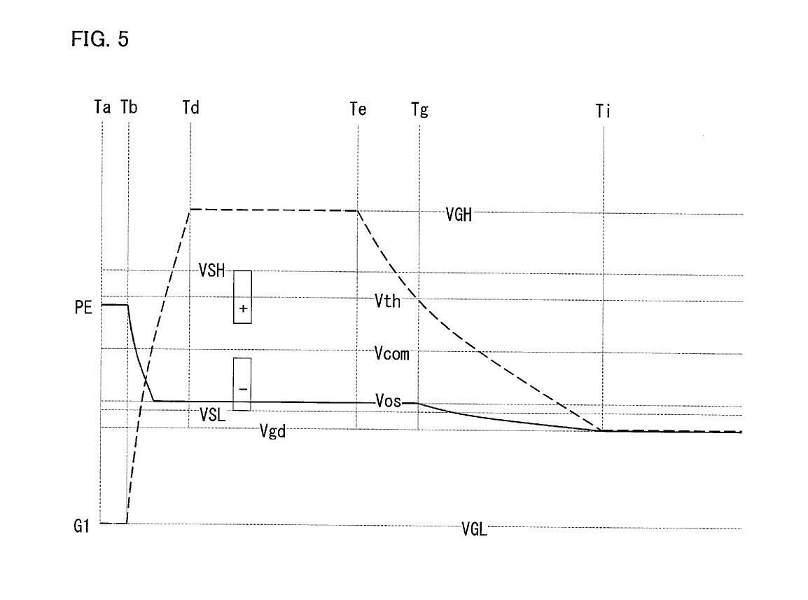

During a period after the time Tg, the electric potential of the gate pulse signal (electric potential of the scan signal line G1) decreases from the threshold potential Vth of the transistor to the ground potential Vgd. During the period, the transistor TR is turned off (a resistance between the source electrode of the transistor TR and the pixel electrode PE is extremely high). This, along with the parasitic capacitance Cgd, causes the electric potential of the pixel electrode PE to decrease from the offset potential Vos to the ground potential Vgd (i.e. kickback, see FIG. 5). The electric potential of the common electrode COM during this period is the ground potential Vgd. Therefore, in view of (i) the threshold potential Vth of the transistor, (ii) various capacitances around the pixel and the transistor (including the parasitic capacitance), and (iii) the like, the offset potential Vos in this case is set to an electric potential which is obtained by adding a kickback voltage (absolute value) to the ground potential Vgd.

Embodiment 1 brings about the following effect: Since, during a period between the time Tb and the time Tg, the ground potential Vgd and the offset potential Vos (>ground potential Vgd) are supplied to the common electrode COM and the data signal line SL, respectively, it is possible to largely eliminate an electric potential difference between the pixel electrode PE and the common electrode COM (i.e. DC voltage across the pixel Pix) even in a case where potential variation (kickback) occurs at the pixel electrode PE after the time Tg at which the transistor TR is turned off.

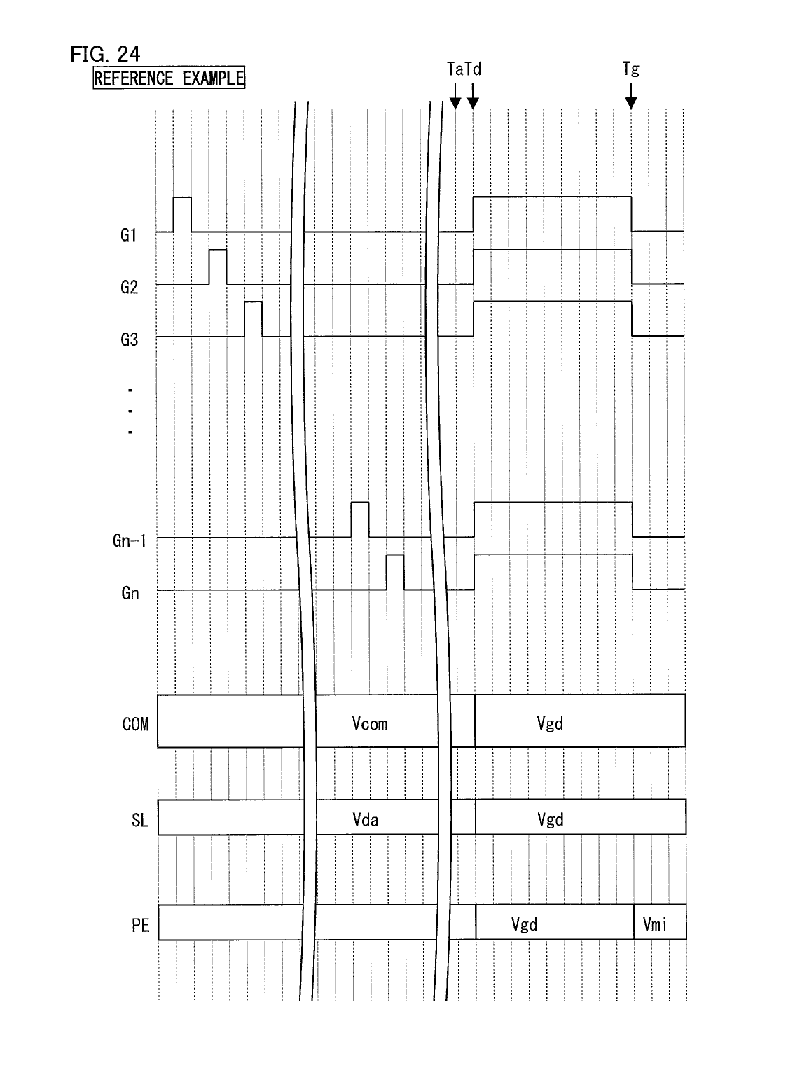

FIGS. 24 through 27 are views showing reference examples in which a ground potential Vgd is supplied to a data signal line SL and to a common electrode COM at time Tb. These examples indicate that, after time Tg at which the transistor TR is turned off, potential variation (kickback) at the pixel electrode PE causes a DC voltage to be applied across the pixel electrode PE and the common electrode COM (i.e. pixel Pix) even after the power supply is turned off (until self-discharge via the transistor TR ends). In particular, in a case where an oxide semiconductor (e.g. oxide semiconductor InGaZnOx containing indium, gallium, and zinc) is used for a semiconductor layer of the transistor TR, on-state/off-state characteristics are so excellent as to prevent self-discharge from easily occurring (described later). This causes the DC voltage to be applied across the pixel Pix for an extended period of time. In other words, in a case where an oxide semiconductor is used for the semiconductor layer of the transistor TR, the effect of Embodiment 1 becomes significant.

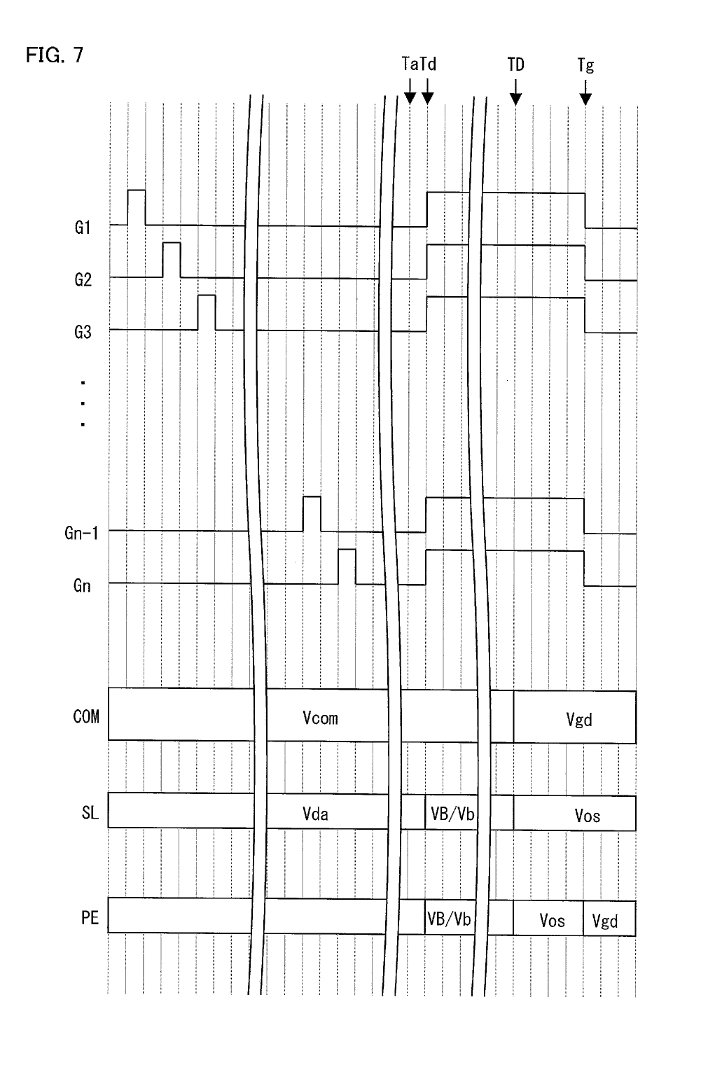

According to Embodiment 1, as illustrated in FIG. 7, a period between the time Td (at which the electric potential of the scan signal line G1 rises) and time TD (before the time Te) can be set as a black-display period. During the black-display period, the common electrode COM receives a Vcom whereas the data signal line alternately receives (i) a black-display potential VB having a greater value than the display center potential Vcom and (ii) a black-display potential Vb (fifth electric potential) having a less value than the display center potential Vcom. At time Tc at which the black-display period ends, the common electrode COM receives the ground potential Vgd whereas the data signal line SL receives the offset potential Vos (>ground potential Vgd).

### Embodiment 2

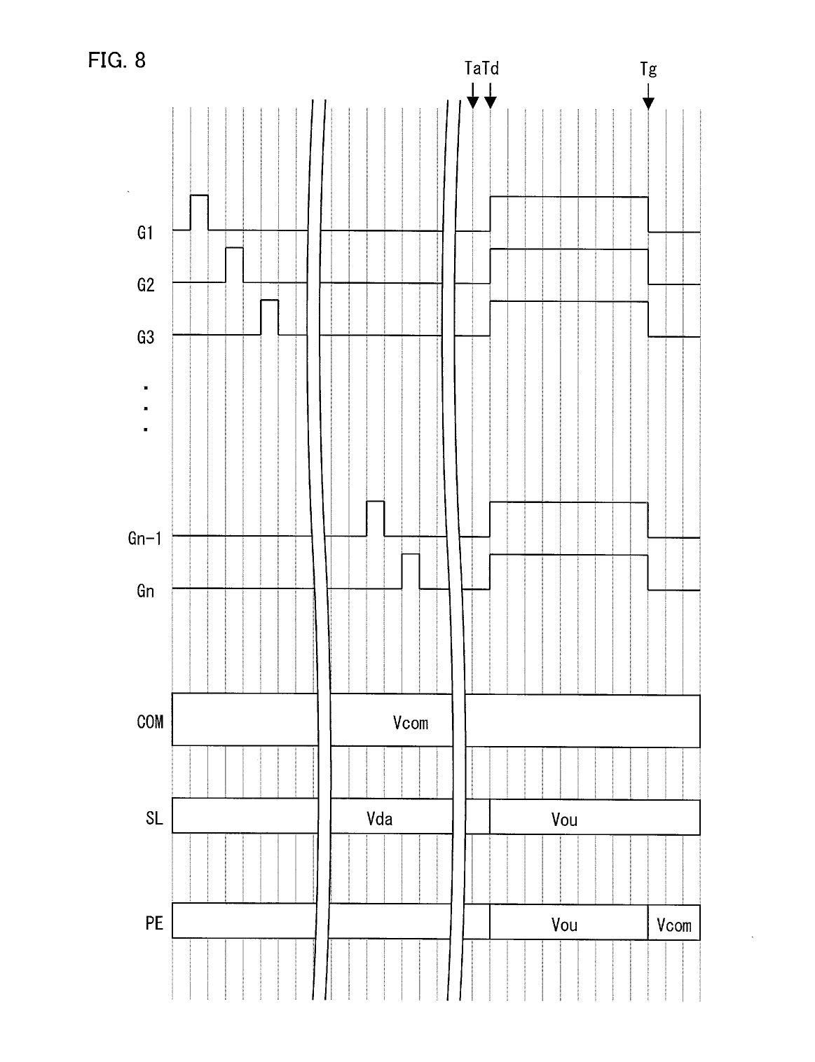

A configuration of a liquid crystal display device of Embodiment 2 is as illustrated in FIG. 2. The liquid crystal display device of Embodiment 2 is configured such that (I) at time Tb, (a) an electric potential of a scan signal line G1 rises from a gate-off potential VGL, (b) an offset potential Vou is supplied to a data signal line SL, and (c) a display center potential Vcom is supplied to a common electrode COM and (II) at time Td, (a) the data signal line SL is charged at the offset potential Vou and (b) the common electrode COM is charged at the display center potential Vcom (see FIGS. 8 through 11).

At time Te which comes after the time Td, the electric potential of a gate pulse signal (electric potential of the scan signal line G1) falls (decreases) from an active level VGH. At time Tg (second timing) which comes after the time Te, the electric potential of the gate pulse signal (electric potential of the scan signal line G1) falls lower than a threshold potential Vth of the transistor. This causes the transistor TR to be turned off.

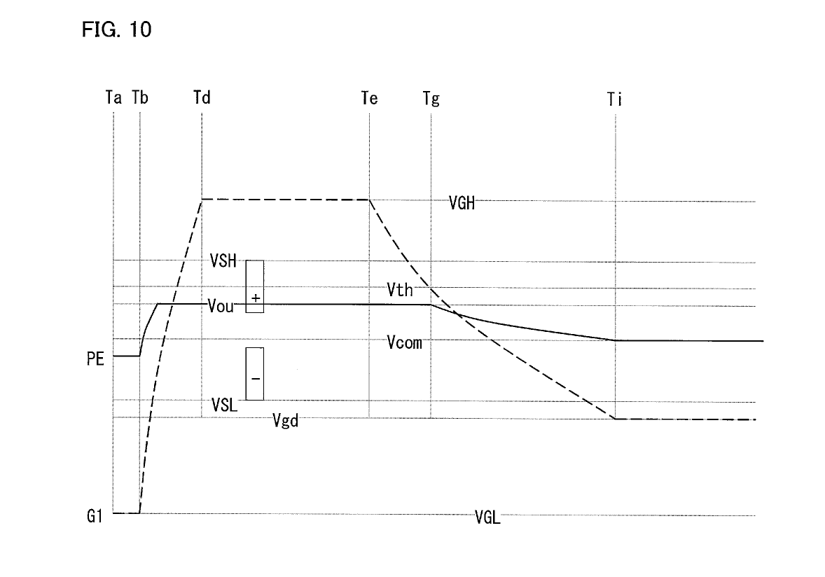

During a period after the time Tg, the electric potential of the gate pulse signal (electric potential of the scan signal line G1) decreases from the threshold potential Vth of the transistor to the ground potential Vgd. During the period, the transistor TR is turned off (a resistance between a source electrode of the transistor TR and a pixel electrode PE is extremely high). This, along with a parasitic capacitance Cgd, causes an electric potential of the pixel electrode PE to decrease from the offset potential Vou to the display center potential Vcom (i.e. kickback, see FIG. 10). The electric potential of the common electrode COM during this period is the display center potential Vcom. Therefore, in view of (i) the threshold potential Vth of the transistor, (ii) various capacitances around the pixel and the transistor (including the parasitic capacitance), and (iii) the like, the offset potential Vou in this case is set to an electric potential which is obtained by adding a kickback voltage (absolute value) to the ground potential Vgd.

### Embodiment 3

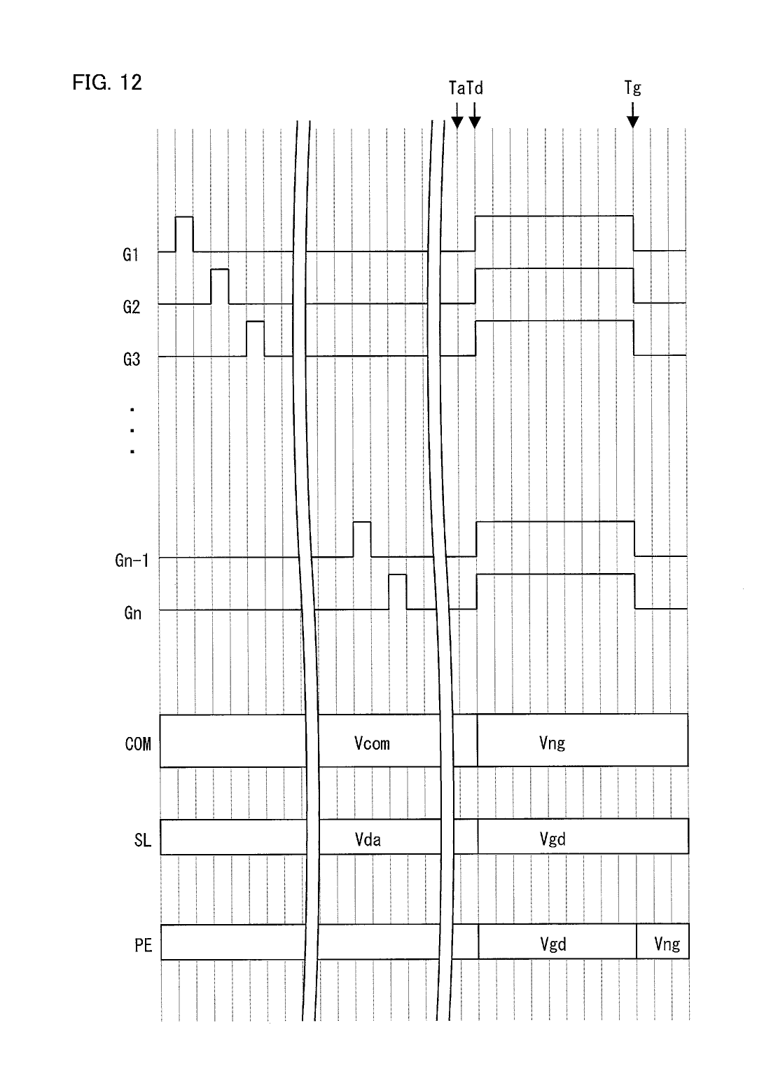

A configuration of a liquid crystal display device of Embodiment 3 is as illustrated in FIG. 2. The liquid crystal display device of Embodiment 2 is configured such that (I) at time Tb, (a) rising of an electric potential of a scan signal line G1 is initiated, (b) a ground potential Vgd is supplied to a data signal line SL, and (c) a negative potential Vng is supplied to a common electrode COM and (II) at time Td (first timing), the electric potential of the scan signal line G1 reaches a gate-on potential VGH (first electric potential) which is higher than a threshold potential Vth of a transistor (see FIGS. 12 through 15).

At time Te which comes after the time Td, the electric potential of a gate pulse signal (electric potential of the scan signal line G1) turns downwards. Then, the transistor TR becomes turned off around time Tg at which the electric potential of the scan signal line G1 becomes equal to the threshold potential Vth of the transistor.

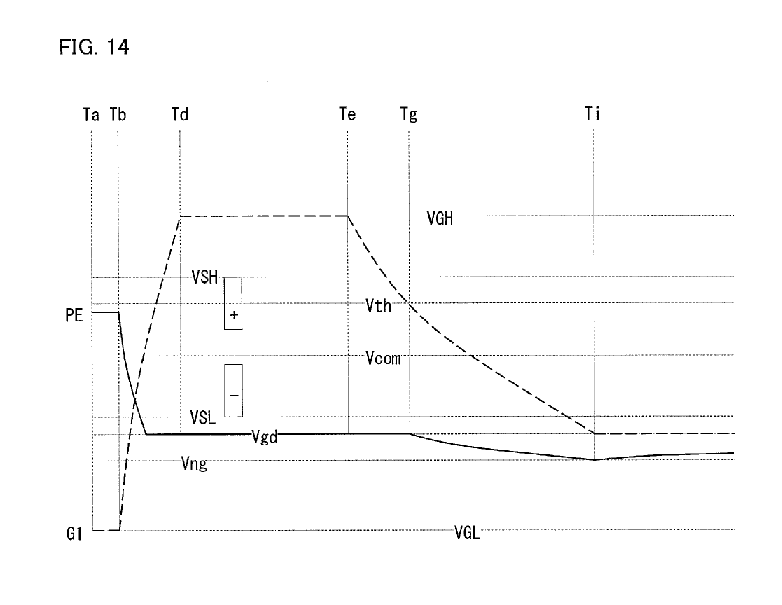

During a period after the time Tg, the electric potential of the gate pulse signal (electric potential of the scan signal line G1) decreases from the threshold potential Vth of the transistor to the ground potential Vgd. During the period, the transistor TR is turned off (a resistance between a source electrode of the transistor TR and a pixel electrode PE is extremely high). This, along with a parasitic capacitance Cgd, causes the electric potential of the pixel electrode PE to decrease from the ground potential Vgd to the negative potential Vng (i.e. kickback, see FIG. 14). The electric potential of the common electrode COM during this period is the ground potential Vgd. Therefore, in view of (i) the threshold potential Vth of the transistor, (ii) various capacitances around the pixel and the transistor (including the parasitic capacitance), and (iii) the like, the negative potential Vng in this case is set to an electric potential which is obtained by subtracting a kickback voltage (absolute value) from the ground potential Vgd.

Embodiment 3 brings about the following effect: Since, during a period between the time Tb and the time Tg, the ground potential Vgd and the negative potential Vng (<ground potential Vgd) are supplied to the data signal line SL and the common electrode COM, respectively, it is possible to largely eliminate an electric potential difference between the pixel electrode PE and the common electrode COM (i.e. DC voltage across a pixel Pix) even in a case where potential variation (kickback) occurs at the pixel electrode PE after the time Tg at which the transistor TR is turned off.

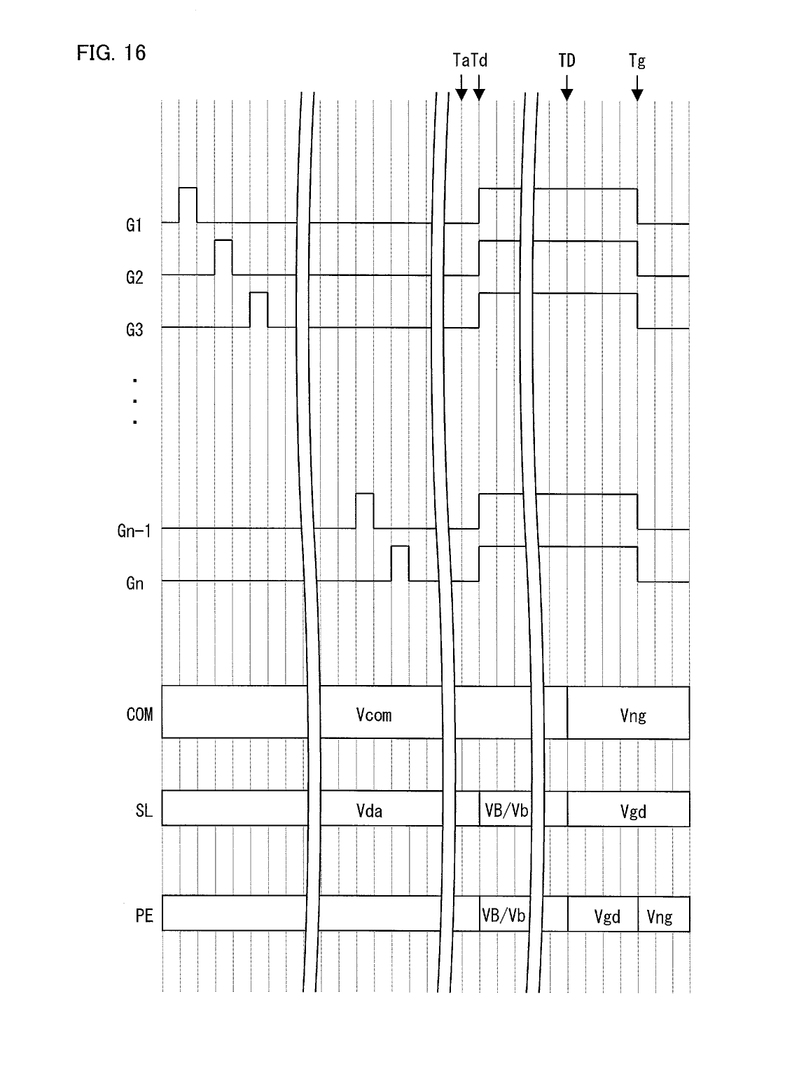

According to Embodiment 3, as illustrated in FIG. 16, a period between the time Td (at which the electric potential of the scan signal line G1 rises) and time TD (before the time Te) can be set as a black-display period. During the black-display period, the common electrode COM receives a Vcom whereas the data signal line alternately receives (i) a black-display potential VB having a greater value than the display center potential Vcom and (ii) a black-display potential Vb having a less value than the display center potential Vcom. At time TD at which the black-display period ends, the data signal line SL receives the ground potential Vgd whereas the common electrode COM receives the negative potential Vng.

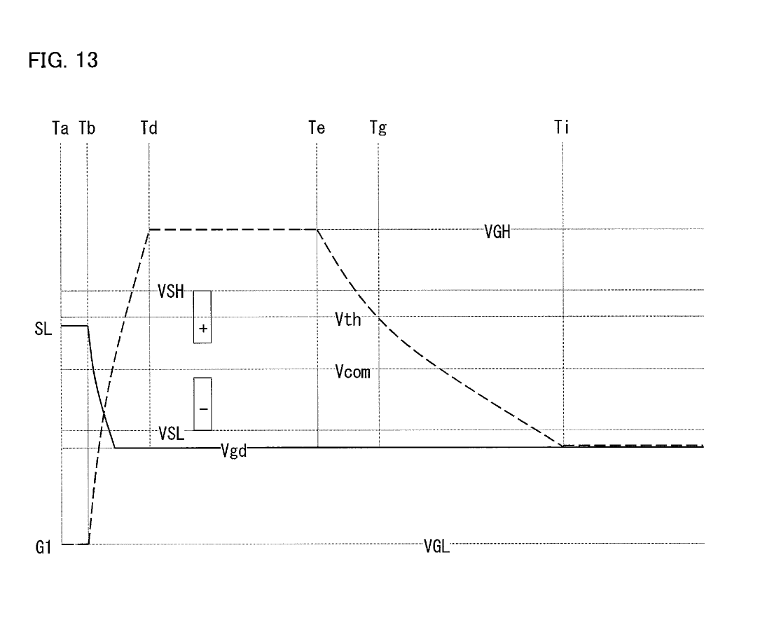

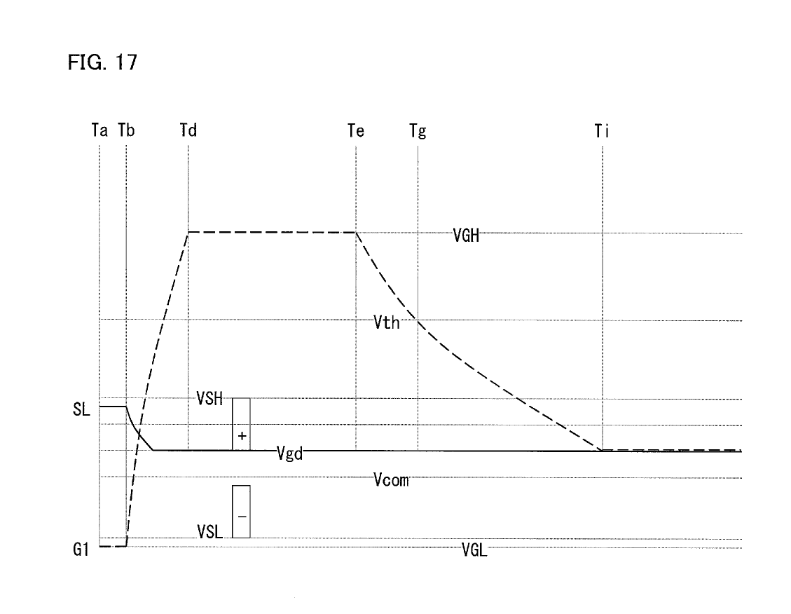

In each of the illustrations of FIGS. 13 through 15, the following is true: Vng<Vgd<VSL<Vcom<VSH. However, the present invention is not limited to such illustrations. For example, the present invention can be modified as VSL<Vcom<VNG<ground potential Vgd<VSH (see FIGS. 17 through 19). This avoids trouble of creating negative potentials only for the sake of a power-off sequence.

[Remarks on Embodiments]

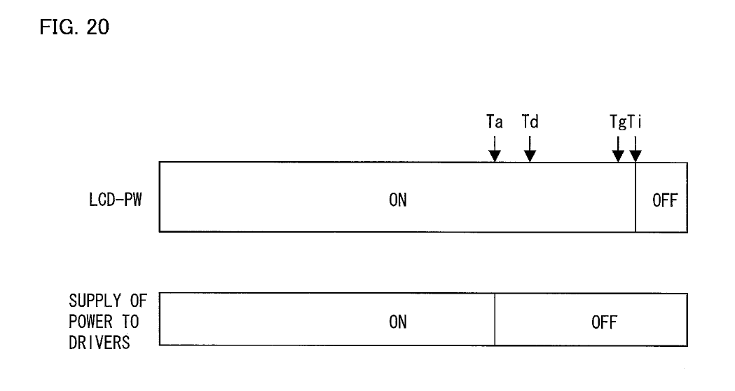

According to the above embodiments, as illustrated in FIG. 20, the power supply circuit PWC stops, at the time Ta, supplying power to the drivers D (GD, SD, and CMD). Then, a sequence from the time Ta through time T1 is carried out, depending on residual voltages of the drivers D (GD, SD, and CMD). Note, however, that the power supply circuit PWC can supply power to the drivers until the time T1.

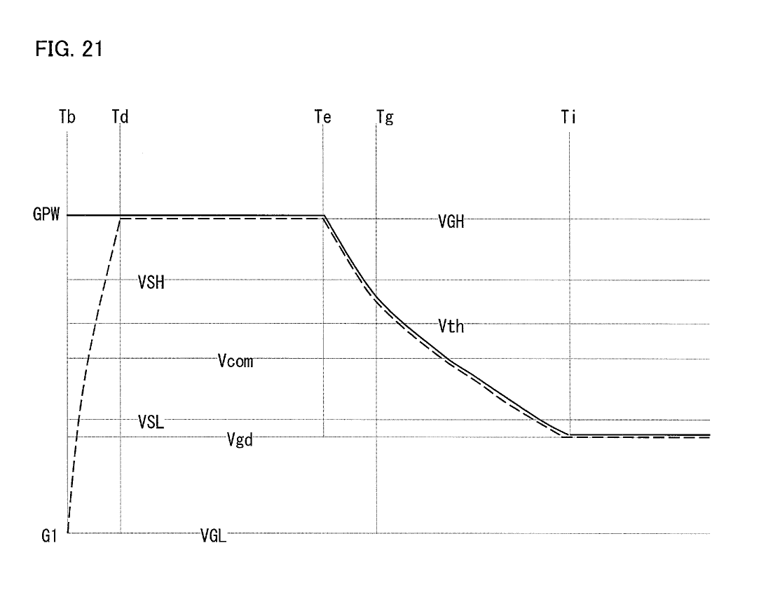

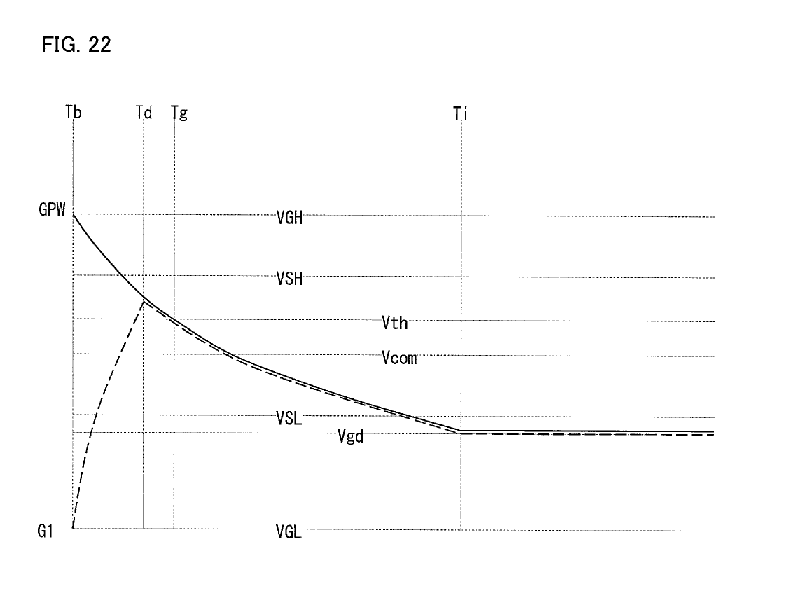

According to each of the liquid crystal display devices of the above embodiments, the power supply circuit PWC stops supplying power to the drivers D (GD, SD, and CSD) at the time Ta. This causes, for example, a power source potential GPW (supplied to the gate driver) to be maintained until the time Te but then decrease by self-discharge (see FIG. 21). Note that in a case where the power source potential GPW has already decreased at the time Tb, the power source potential GPW changes as illustrated in FIG. 22. In a case of FIG. 22, the transistor TR is turned on by causing the scan signal line G1 to rise, at the time Td (first timing), to an electric potential (first electric potential; electric potential lower than the gate-on potential VGH) which is higher than the threshold potential Vth of the transistor.

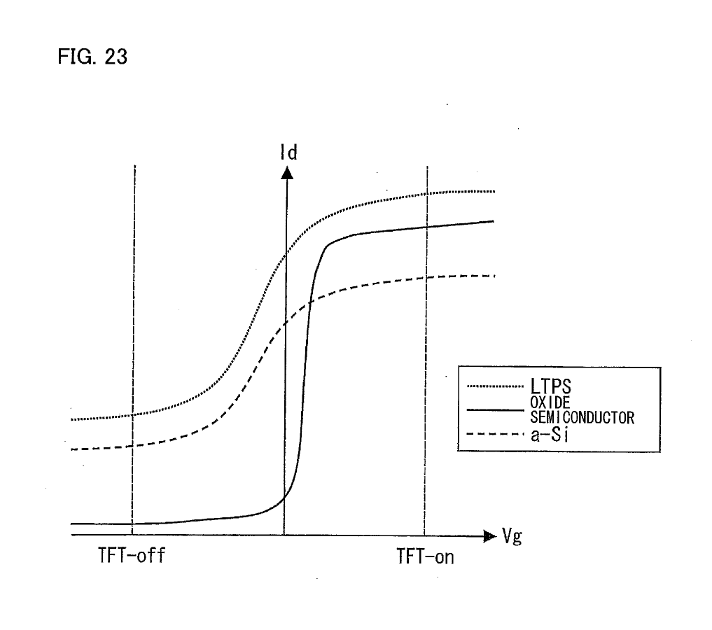

According to each of the liquid crystal display devices of the above embodiments, it is desirable that a TFT, in which a semiconductor layer is formed by what is known as an oxide semiconductor, be used as a transistor of a liquid crystal panel. Examples of the oxide semiconductor encompass an oxide semiconductor (InGaZnOx) containing indium, gallium, and zinc. FIG. 23 shows respective characteristics of (i) a TFT employing an oxide semiconductor, (ii) a TFT employing a-Si (amorphous silicon), and (iii) a TFT employing LTPS (Low Temperature Poly Silicon). In FIG. 23, a horizontal axis (Vg) indicates a gate voltage supplied to the TFTs, and a vertical axis (Id) indicates a value of an electric current through respective source-to-drain connections of the TFTs (In FIG. 23, a period shown as “TFT-on” indicates a period in which the TFTs are turned on whereas a period shown as “TFT-off” indicates a period in which the TFTs are turned off). As illustrated in FIG. 23, an on-state current/off-state current ratio of the oxide semiconductor TFT is 1,000 times or more higher than that of a-Si TFT. This indicates that the oxide semiconductor TFT has quite excellent on-state/off-state characteristics.

Specifically, a leak current while the oxide semiconductor TFT is turned off is approximately 1/100 of a leak current while the a-Si TFT is turned off. That is, an off-state characteristic of the oxide semiconductor TFT is so excellent as to hardly allow a leak current. Note, however, that the quite excellent off-state characteristic leaves a high possibility of electric charge remaining in a pixel for an extended period of time while the TFT is turned off.

The liquid crystal display device of the present invention includes: a data signal line; a scan signal line; a pixel electrode; a transistor connected to (i) the data signal line, (ii) the scan signal line, and (iii) the pixel electrode; and a common electrode, the liquid crystal display device being configured to turn on the transistor during a power-off sequence by causing a change in an electric potential of the scan signal line, the electric potential of the scan signal line increasing up to a first electric potential at a first timing after the change is initiated, and an output electric potential supplied to the data signal line at a second timing which comes after the first timing being set to a value higher than an output electric potential supplied to the common electrode at the second timing.

With the configuration, it is possible to cause the pixel electrode to discharge electric charge by turning on the transistor after the first timing of the power-off sequence. In addition, the output electric potential supplied to the data signal line at the second timing after the first timing is set to a value higher than the output electric potential supplied to the common electrode at the second timing. This makes it unlikely for a DC voltage to be applied across a pixel even if an electric potential reduction (kickback) occurs at the pixel electrode in reaction to a change in status of the transistor from an on state to an off state.

The liquid crystal display device can be configured such that: the output electric potential supplied to the common electrode at the second timing is a second electric potential; and the output electric potential supplied to the data signal line at the second timing is a third electric potential.

The liquid crystal display device can be configured such that: the output electric potential supplied to the common electrode at the second timing is a fourth electric potential; and the output electric potential supplied to the data signal line at the second timing is a second electric potential.

The liquid crystal display device can be configured such that the first electric potential is equal to or higher than a threshold potential of the transistor.

The liquid crystal display device can be configured such that the second electric potential is a ground potential.

The liquid crystal display device can be configured such that the fourth electric potential is lower than a ground potential.

The liquid crystal display device can be configured such that an electric potential of the common electrode during normal display is the fourth electric potential.

The liquid crystal display device can be configured such that, after the first timing, (i) an output electric potential supplied to the common electrode is set to a fifth electric potential and then set to the second electric potential and (ii) an output electric potential supplied to the data signal line is set to a sixth electric potential and then set to the third electric potential.

The liquid crystal display device can be configured such that, after the first timing, (i) an output electric potential supplied to the common electrode is set to a fifth electric potential and then set to a third electric potential and (ii) an output electric potential supplied to the data signal line is set to a sixth electric potential and then set to the second electric potential.

The liquid crystal display device can be configured such that a pixel including the pixel electrode carries out black display by (i) setting, to the fifth electric potential, an output electric potential supplied to the common electrode and (ii) causing the data signal line to write the sixth electric potential into the pixel electrode.

The liquid crystal display device can be configured to further include: a data signal line drive circuit for generating an output electric potential to be supplied to the data signal line; a common electrode drive circuit for generating an output electric potential to be supplied to the common electrode; and a control circuit for controlling the data signal line drive circuit and the common electrode drive circuit.

The liquid crystal display device can be configured such that an oxide semiconductor is used for a semiconductor layer of the transistor.

The liquid crystal display device can be configured such that the oxide semiconductor contains indium, gallium, and zinc.

A method of the present invention is a method of driving a liquid crystal display device, said liquid crystal display device including: a data signal line; a scan signal line; a pixel electrode; a transistor connected to (i) the data signal line, (ii) the scan signal line, and (iii) the pixel electrode; and a common electrode, the liquid crystal display device being configured to turn on the transistor during a power-off sequence by causing a change in an electric potential of the scan signal line, said method including the steps of: increasing the electric potential of the scan signal line up to a first electric potential at a first timing after the change is initiated; and setting an output electric potential, which is supplied to the data signal line at a second timing which comes after the first timing, to a value higher than an output electric potential supplied to the common electrode at the second timing.

The present invention is not limited to the description of the embodiments, but can be altered in many ways by a person skilled in the art within the scope of the claims. An embodiment derived from a proper combination of technical means disclosed in different embodiments is also encompassed in the technical scope of the present invention.

### INDUSTRIAL APPLICABILITY

A liquid crystal display device of the present invention is suitable for, for example, various liquid crystal displays and various liquid crystal televisions.

### REFERENCE SIGNS LIST

LCD Liquid crystal display device
TR Transistor
COM Common electrode
SL Data signal line
G1 through Gn Scan signal line
CMD Common electrode driver
SD Source driver
GD Gate driver
AM Active matrix substrate
LCP Liquid crystal panel
PE Pixel electrode
DCC Display control circuit
PWC Power supply circuit

1-14. (canceled)

15. A liquid crystal display device comprising:
a data signal line;
a scan signal line;
a pixel electrode;
a transistor connected to (i) the data signal line, (ii) the scan signal line, and (iii) the pixel electrode; and
a common electrode,
the liquid crystal display device being configured to turn on the transistor during a power-off sequence by causing a change in an electric potential of the scan signal line,
the electric potential of the scan signal line increasing up to a first electric potential at a first timing after the change is initiated, and
an output electric potential supplied to the data signal line at a second timing which comes after the first timing being set to a value higher than an output electric potential supplied to the common electrode at the second timing.

16. The liquid crystal display device as set forth in claim 15, wherein:
the output electric potential supplied to the common electrode at the second timing is a second electric potential; and
the output electric potential supplied to the data signal line at the second timing is a third electric potential.

17. The liquid crystal display device as set forth in claim 15, wherein:
the output electric potential supplied to the common electrode at the second timing is a fourth electric potential; and
the output electric potential supplied to the data signal line at the second timing is a second electric potential.

18. The liquid crystal display device as set forth in claim 15, wherein the first electric potential is equal to or higher than a threshold potential of the transistor.

19. The liquid crystal display device as set forth in claim 16, wherein the second electric potential is a ground potential.

20. The liquid crystal display device as set forth in claim 17, wherein the fourth electric potential is lower than a ground potential.

21. The liquid crystal display device as set forth in claim 20, wherein an electric potential of the common electrode during normal display is the fourth electric potential.

22. The liquid crystal display device as set forth in claim 16, wherein, after the first timing, (i) an output electric potential supplied to the common electrode is set to a fifth electric potential and then set to the second electric potential and (ii) an output electric potential supplied to the data signal line is set to a sixth electric potential and then set to the third electric potential.

23. The liquid crystal display device as set forth in claim 17, wherein, after the first timing, (i) an output electric potential supplied to the common electrode is set to a fifth electric potential and then set to a fourth electric potential and (ii) an output electric potential supplied to the data signal line is set to a sixth electric potential and then set to the second electric potential.

24. The liquid crystal display device as set forth in claim 22, wherein a pixel including the pixel electrode carries out black display by (i) setting, to the fifth electric potential, an output electric potential supplied to the common electrode and (ii) causing the data signal line to write the sixth electric potential into the pixel electrode.

25. A liquid crystal display device as set forth in claim 15, further comprising:
a data signal line drive circuit for generating an output electric potential to be supplied to the data signal line;
a common electrode drive circuit for generating an output electric potential to be supplied to the common electrode; and
a control circuit for controlling the data signal line drive circuit and the common electrode drive circuit.

26. The liquid crystal display device as set forth in claim 15, wherein an oxide semiconductor is used for a semiconductor layer of the transistor.

27. The liquid crystal display device as set forth in claim 26, wherein the oxide semiconductor contains indium, gallium, and zinc.

28. A method of driving a liquid crystal display device,
said liquid crystal display device comprising:
a data signal line;
a scan signal line;
a pixel electrode;
a transistor connected to (i) the data signal line, (ii) the scan signal line, and (iii) the pixel electrode; and
a common electrode,
the liquid crystal display device being configured to turn on the transistor during a power-off sequence by causing a change in an electric potential of the scan signal line,
said method comprising the steps of:
increasing the electric potential of the scan signal line up to a first electric potential at a first timing after the change is initiated; and
setting an output electric potential, which is supplied to the data signal line at a second timing which comes after the first timing, to a value higher than an output electric potential supplied to the common electrode at the second timing.
